(19) United States
(12) Patent Application Publication
(10) Pub. No.: US 2026/0197990 A1
(43) Pub. Date: Jul. 9, 2026

(54) SEMICONDUCTOR MEMORY DEVICE

(71) Applicant: Unisantis Electronics Singapore Pte. Ltd., Singapore (SG)

(72) Inventors: Masakazu KAKUMU, Tokyo (JP); Takashi Ohsawa, Tokyo (JP); Nozomu Harada, Tokyo (JP)

(21) Appl. No.: 19/426,875

(22) Filed: Dec. 19, 2025

(30) Foreign Application Priority Data
Jan. 7, 2025 (JP) 2025-002414

(51) Int. Cl. H10B 12/00; G11C 11/404

(52) U.S. Cl. CPC H10B 12/20; G11C 11/404

(57) ABSTRACT

A p layer extends parallel to the substrate, part of the p layer is coated with a first gate insulating layer, a first gate conductor layer covers part of the first gate insulating layer, a second gate insulating layer covers part of the p layer, a second gate conductor layer covers part of the second gate insulating layer, and an n+ layer and another n+ layer are provided in part of the p layer interposed between the first and second gate conductor layers. The first gate conductor layer functions as a gate, one of the n+ layers functions as a source, and the other n+ layer functions as a drain to perform a MOSFET operation. Respective voltages of a bit line, a source line, a word line, a plate line are operated so as to perform a memory operation of an FX-RAM.

### CROSS-REFERENCE TO RELATED APPLICATIONS

This application claims priority to JP2025-002414, filed January 7, 2025, the entire content of which is incorporated herein by reference.

### BACKGROUND OF THE INVENTION

### 1. Field of the Invention

The present invention relates to a semiconductor memory device.

### 2. Description of the Related Art

Today, in technical development of large scale integration (LSI), there is a demand for higher integration, higher performance, lower power consumption, and higher functionality of memory elements.

As an integrated-circuit memory, a dynamic random access memory (DRAM) is widely used. For improving the density of the DRAM, for example, the following DRAMs are used: a DRAM in which a surrounding gate transistor (SGT) structure using a continuous arrangement in a direction perpendicular to an upper surface of a semiconductor substrate is used (see, for example, Japanese Unexamined Patent Application Publication No. 2-188966, Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991), and H. Chung, H. Kim, H. Kim, K. Kim, S. Kim, K. Dong, J. Kim, Y.C. Oh, Y. Hwang, H. Hong, G. Jin, and C. Chung: “4F2 DRAM Cell with Vertical Pillar Transistor(VPT),” 2011 Proceeding of the European Solid-State Device Research Conference, (2011)); and a capacitorless DRAM cell including a single MOS transistor (see T. Ohsawa, K. Fujita, T. Higashi, Y. Iwata, T. Kajiyama, Y. Asao, and K. Sunouchi: “Memory Design Using a One-Transistor Gain Cell on SOI,” IEEE Journal of Solid State Circuits, Vol. 37, No. 11, pp. 1510-1522 (2002), J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32nm Node and Beyond,” IEEE IEDM (2006), and E. Yoshida: “A Capacitorless 1T-DRAM Technology Using Gate-Induced Drain-Leakage (GIDL) Current for Low-Power and High-Speed Embedded Memory,” IEEE IEDM (2006)). This is popularly called a "1T DRAM". For example, part or the entirety of a positive hole group out of the positive holes and the electron group generated in a channel by impact ionization due to a current between a source and a drain of an n-channel metal oxide semiconductor (MOS) transistor is held in the channel to write logical storage data "1". Logical storage data "0" is written by discharging the positive hole group from the channel. However, there is a problem with this structure in that the application of the voltage to the selected cells causes input of undesired signals into non-selected cells, leading to malfunctioning of the non-selected memory cells.

There also is a capacitorless dynamic flash memory (DFM) on a silicon on insulator (SOI) layer in which a single memory cell includes two gate electrodes (see U.S. Patent Application Publication No. 2023/11776620 B2 and K. Sakui, and N. Harada, “Dynamic Flash Memory with Dual Gate Surrounding Gate Transistor (SGT),” Proc. IEEE IMW, pp. 72-75(2021).). In this memory cell, voltages of four electrodes are operated so as to change a carrier concentration in a floating body to bring about a conducting state or a non-conducting state for performing a memory operation. Furthermore, for example, a structure in which a body for storing carriers is continuous with a lower part of a MOS transistor is proposed (see U.S. Patent Application Publication No. 2023/11798616 B2). Furthermore, for high density, a DRAM formed by a three-dimensional lamination using a sacrificial layer is proposed (see C. S. Hwang, “Dynamic Random Access Memory,” Tutorials of IEEE International Memory Workshop, (2024) and K. S. Choi et al., “A Three Dimensional DRAM (3D DRAM) Technology for the Next Decades,” IEEE Symposium on VLSI Technology Digest of Technical Papers, (2024)). However, for ensuring a sensing margin, a capacitance of the capacitor is still to be maintained at greater than or equal to a certain value. Thus, there is a barrier to reduce the cell size.

### SUMMARY OF THE INVENTION

The present application provides a memory device that suppresses noise due to capacitive coupling between a word line and a body, incorrect rewriting of storage data, and incorrect reading due to instability of memory by using a capacitorless single-transistor type DRAM. Furthermore, a semiconductor memory device that realizes a high density and high-speed performance is provided by introducing a structure in which memory cells are vertically laminated using a nanosheet (see, for example, N. Louber et al., “Stacked Nanosheet Gate-All-Around Transistor to Enable Scaling Beyond FinFET,” IEEE Symposium on VLSI Technology Digest of Technical Papers, pp. T230-T231 (2017)) technique using a sacrificial layer.

In an aspect of the present invention, a memory device using a semiconductor element is provided. The memory device includes a memory cell that includes a semiconductor base extending in a first direction parallel to a substrate, a first gate insulating layer in contact with one end surface of the semiconductor base in the first direction, a first gate conductor layer in contact with the first gate insulating layer without contacting the semiconductor base, a second gate insulating layer spaced apart from the first gate insulating layer in the first direction and covers part of the semiconductor base, a second gate conductor layer in contact with the second gate insulating layer, and a first impurity layer and a second impurity layer provided between the first gate conductor layer and the second gate conductor layer and formed in part of the semiconductor base. The first impurity layer and the second impurity layer are disposed so as to function as a drain or a source for the first gate conductor layer.

The first impurity layer may be connected to a bit line, the second impurity layer may be connected to a source line, the first gate conductor layer may be connected to a word line, and the second gate conductor layer may be connected to a plate line. In this case, memory write and/or memory erase is performed by applying voltages respectively to the source line, the bit line, the plate line, and the word line.

A memory write operation may be performed by performing an operation in which voltages to be applied to a bit line, a source line, a word line, and a plate line are controlled so as to generate an electron group and a positive hole group in the semiconductor base and the second impurity layer using impact ionization due to a current flowed between the first impurity layer and the second impurity layer or using a gate induced drain leakage current, and an operation which causes part or an entirety of the electron group or the positive hole group, out of the generated electron group and the generated positive hole group, as majority carriers in the semiconductor base to remain in the semiconductor base. A memory erase operation may be performed by controlling the voltages to be applied to the bit line, the source line, the word line, and the plate line to extract the remaining electron group or the remaining positive hole group as the majority carriers in the semiconductor base from at least one of the first impurity layer and the second impurity layer.

Part of the first impurity layer and part of the second impurity layer may face each other in a second direction perpendicular to the first direction with the semiconductor base interposed therebetween.

The first impurity layer or the second impurity layer may be in contact with the first gate insulating layer or the second gate insulating layer.

In a section of the memory cell including the first impurity layer and the second impurity layer, for both a start point and an end point of a line segment connecting the first impurity layer and the second impurity layer at a shortest distance, the first gate conductor layer may be disposed in a direction perpendicular to the line segment.

A plurality of the memory cells, a plurality of the first impurity layers, and a plurality of the second impurity layers may be provided. The plurality of memory cells having a shape identical to a shape of the memory cell formed in the semiconductor base may be provided on a first insulating layer disposed on the substrate in a direction perpendicular to the substrate such that central axes of the plurality of memory cells in directions in which the respective memory cells extend are parallel to each other. A first conductor layer connected to the plurality of first impurity layers of the plurality of memory cells and a second conductor layer connected to the plurality of second impurity layers of the plurality of memory cells may be provided.

Among the plurality of memory cells adjacent to each other in a parallel direction or a perpendicular direction relative to the substrate, the first gate conductor layer connected to each memory cell may be shared.

Among the plurality of memory cells adjacent to each other in a parallel direction or a perpendicular direction relative to the substrate, the second gate conductor layer connected to each memory cell may be shared.

Among the plurality of memory cells adjacent to each other in a parallel direction or a perpendicular direction relative to the substrate, the first conductor layer connected to each memory cell may be shared.

Among the plurality of memory cells adjacent to each other in a parallel direction or a perpendicular direction relative to the substrate, the second conductor layer connected to each memory cell may be shared.

### BRIEF DESCRIPTION OF THE DRAWINGS

FIGS. 1A, 1B, and 1C illustrate sectional structures and a bird's-eye view of a memory device using a semiconductor element according to one embodiment.

FIGS. 2A, 2B, and 2C illustrate a first modification of the memory device using a semiconductor element according to the one embodiment.

FIGS. 3A, 3B, 3C, and 3D illustrate a second modification of the memory device using a semiconductor element according to the one embodiment.

FIGS. 4A, 4B, and 4C illustrate storage of carriers and a cell current in a write operation and immediately after the operation of the memory device using a semiconductor element according to the one embodiment.

FIGS. 5A, 5B, and 5C illustrate storage of positive hole carriers, an erase operation, and a cell current immediately after the write operation of the memory device using a semiconductor element according to the one embodiment.

FIGS. 6A, 6B, 6C, and 6D illustrate cell arrangement of the memory device using a semiconductor element according to the one embodiment.

FIGS. 7A and 7B illustrate a developed stated of the cell arrangement illustrated in FIGS. 6A, 6B, 6C, and 6D of the memory device using a semiconductor element according to the one embodiment.

FIGS. 8A and 8B illustrate an application example of the cell arrangement illustrated in FIGS. 7A and 7B of the memory device using a semiconductor element according to the one embodiment.

### DESCRIPTION OF THE PREFERRED EMBODIMENTS

Hereinafter, the structure, a driving method, a behavior of stored carriers, cell arrangement in a semiconductor device, and a wiring structure of a memory device using a semiconductor element according to the present invention will be described with reference to the drawings.

### Embodiment

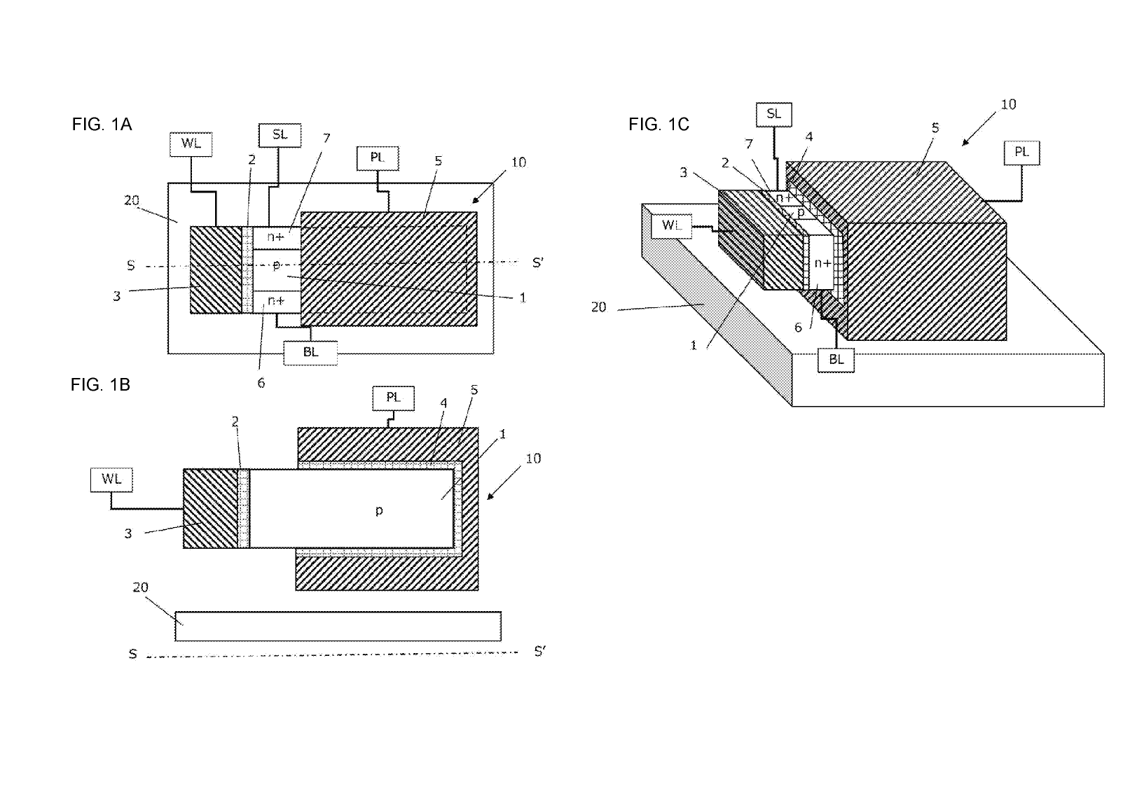

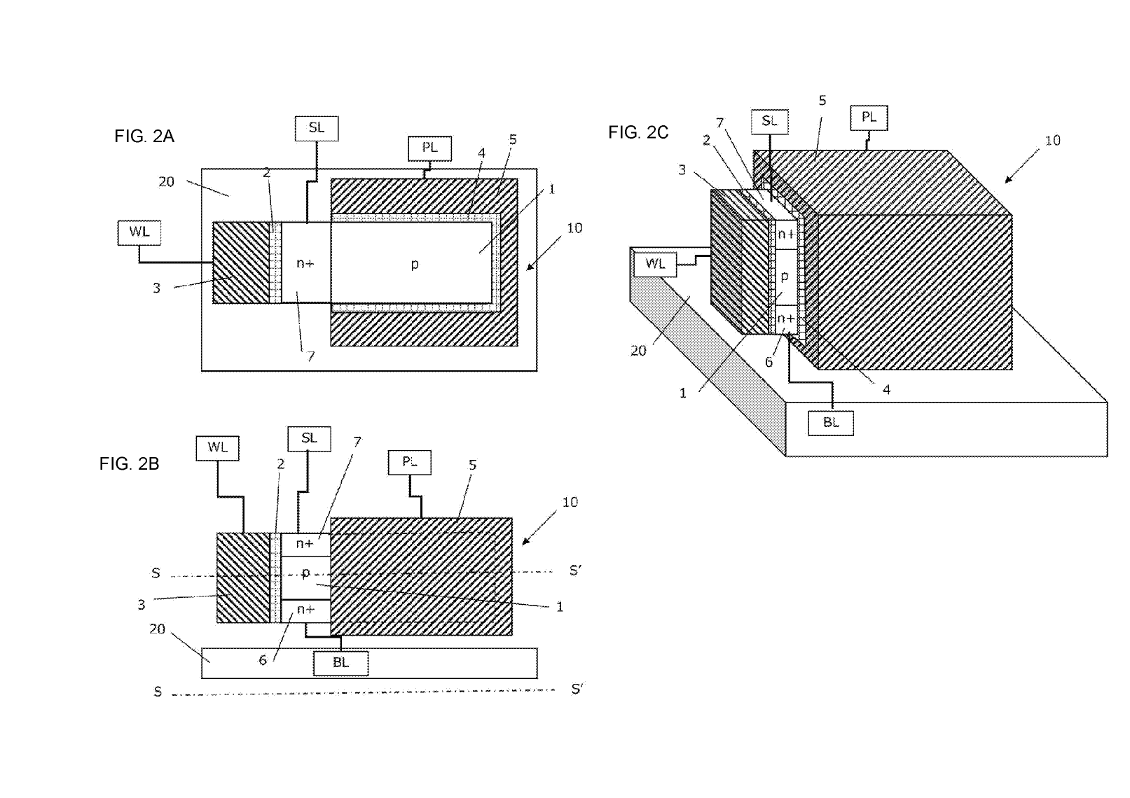

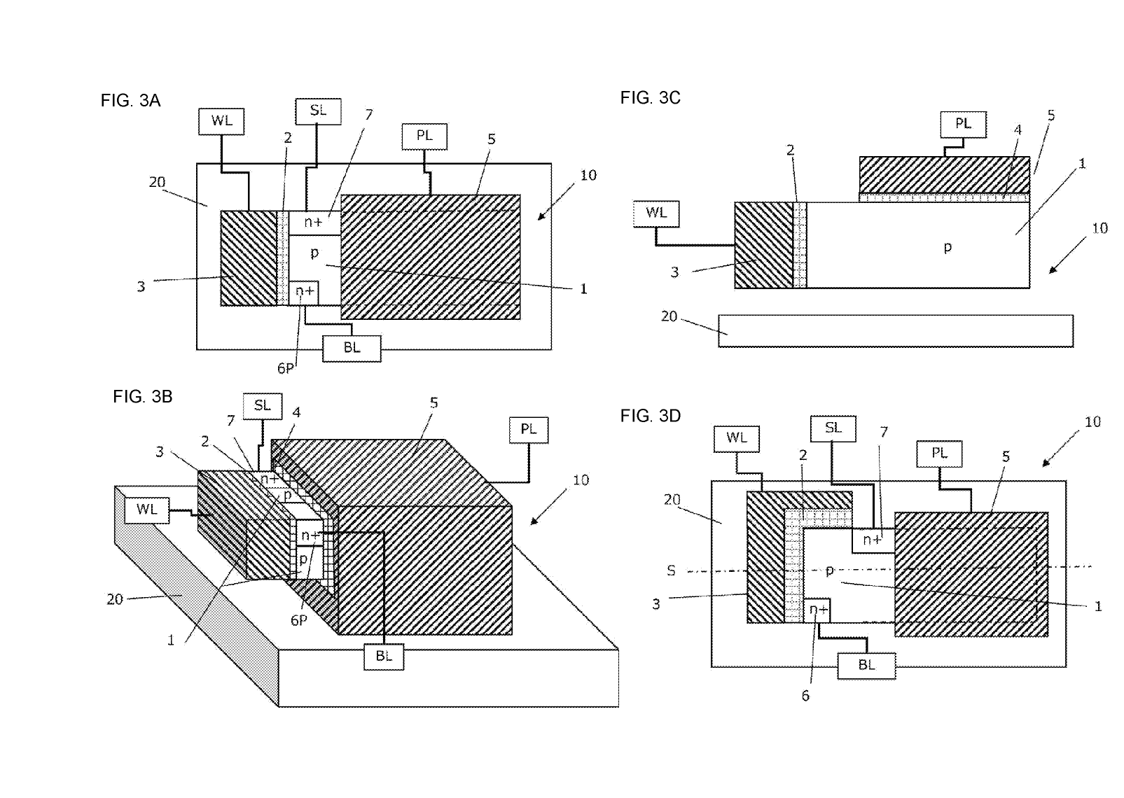

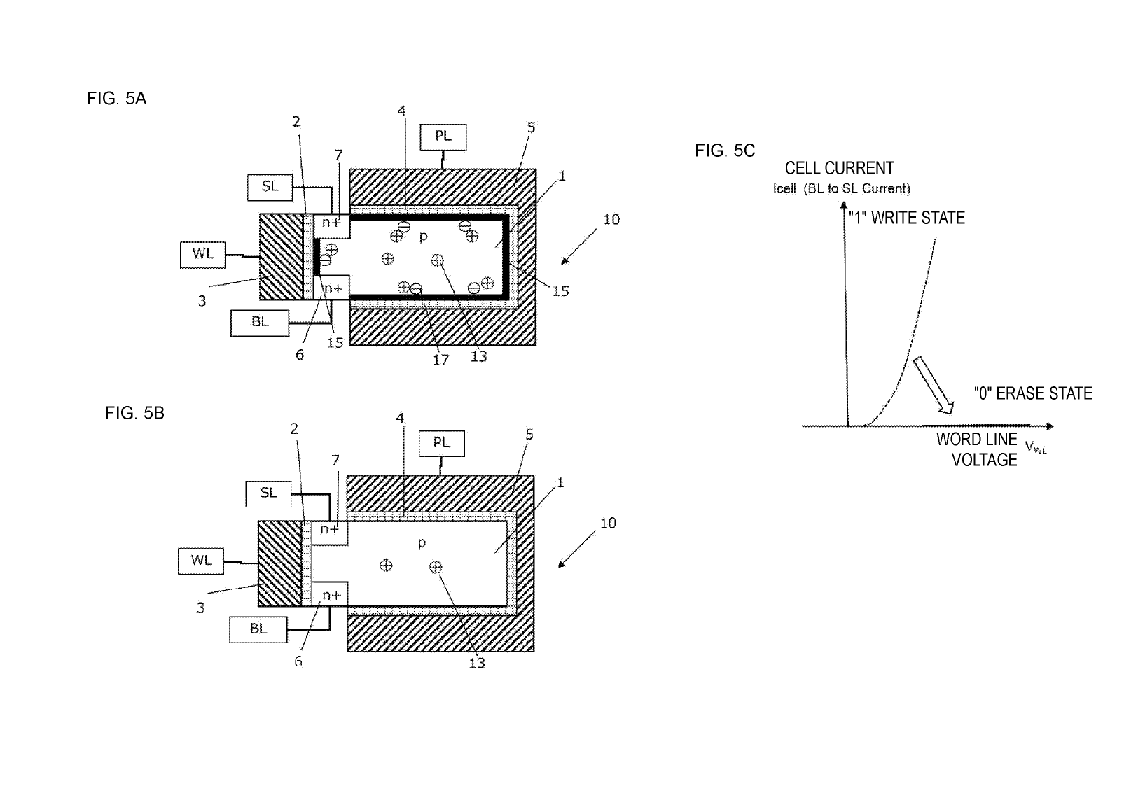

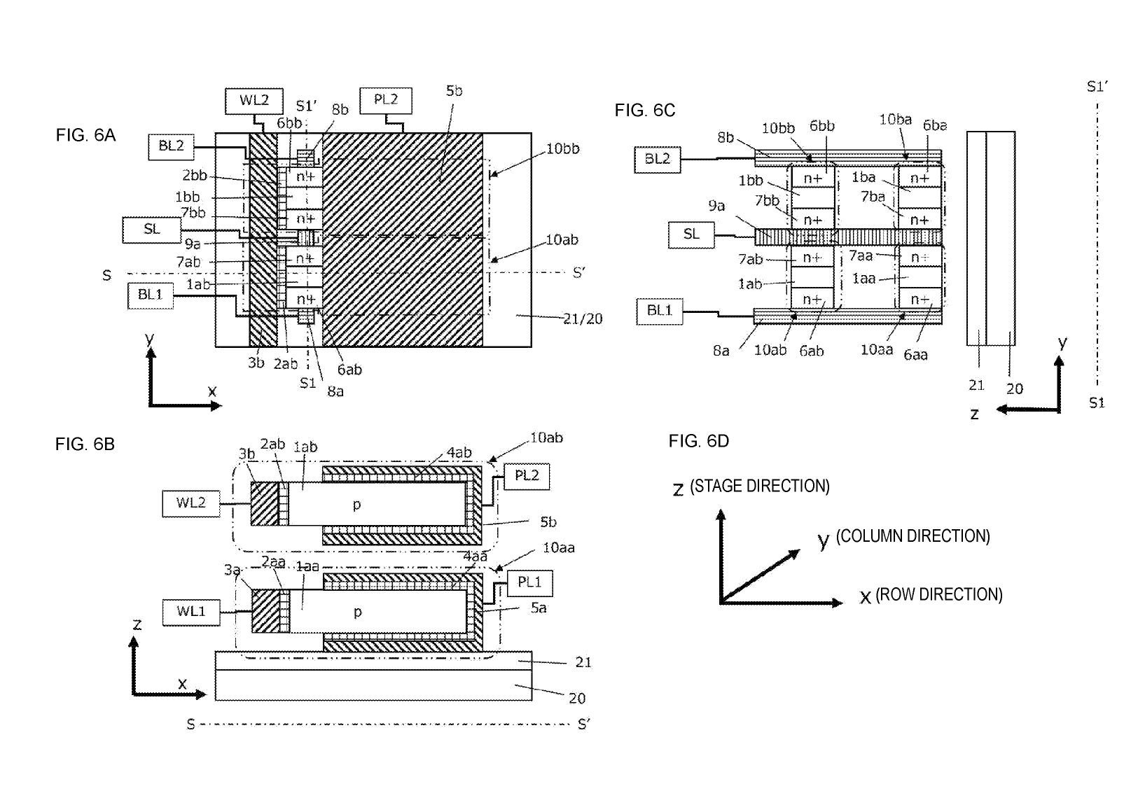

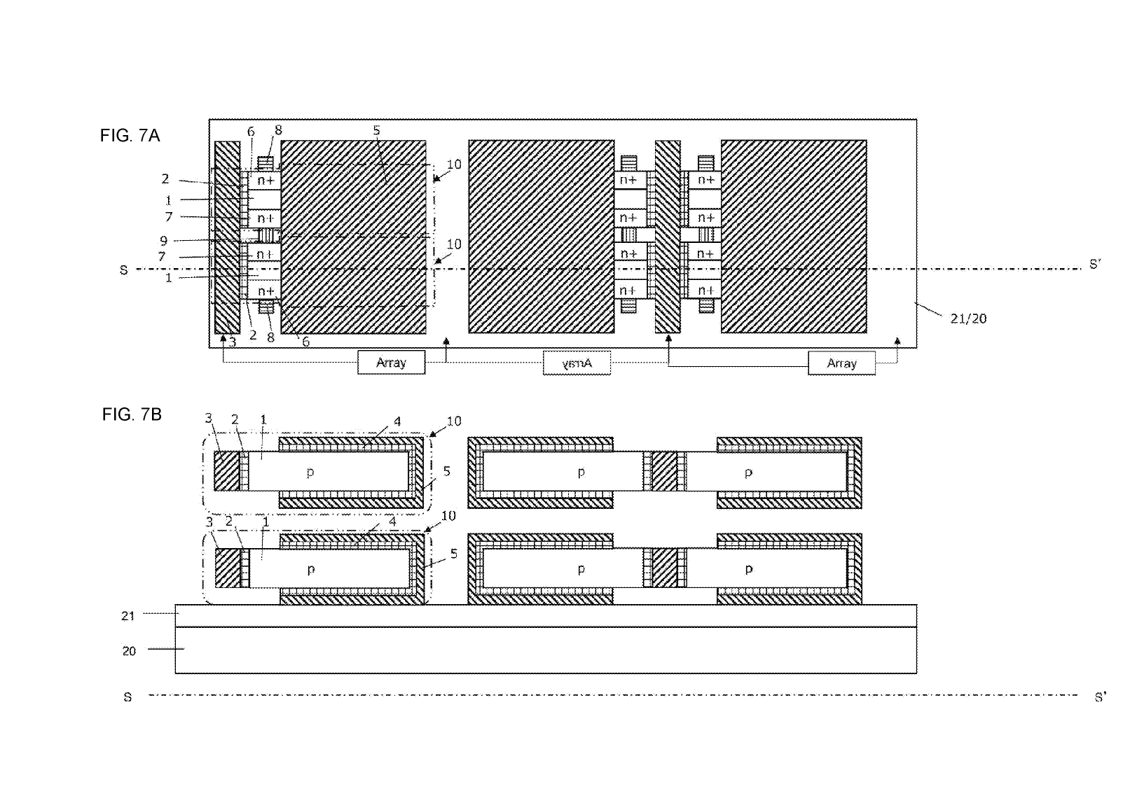

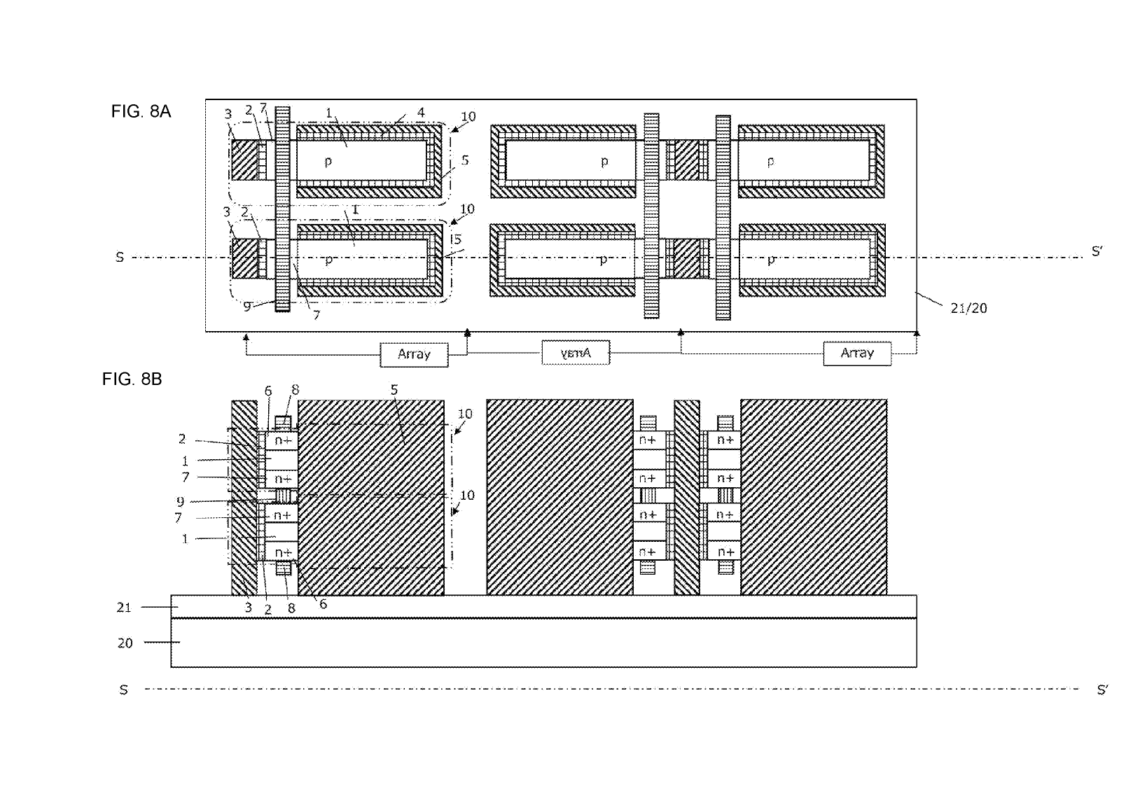

With reference to FIGS. 1A to 5C, the structure and operation mechanism of memory cells using a semiconductor element according to one embodiment of the present invention are described. With reference to FIGS. 1A to 1C, the cell structure of a memory using a semiconductor element is described. With reference to FIGS. 2A to 3D, modifications of the memory using a semiconductor element are described. With reference to 4A to 4C, a memory write mechanism and the behavior of the carriers of the memory using a semiconductor element are described. With reference to FIGS. 5A to 5C, a data erase mechanism is described. With reference to FIGS. 6A to 6D, an example of arrangement of four memory cells of the semiconductor device according to the present embodiment is described. With reference to FIGS. 7A to 8B, a method of developing further arrangement of the memory cells according to the present embodiment is further described.

FIGS. 1A to 1C illustrate the structure of a memory cell using a semiconductor element according to the one embodiment of the present invention. FIG. 1A is a plan view, FIG. 1B is a sectional view taken along line S-S' illustrated in FIG. 1A, and FIG. 1C is a bird's-eye view of the memory cell.

A p layer 1 (serving as an example of a "semiconductor base" according to the present invention, hereinafter, a p-type semiconductor is referred to as a "p layer"), which is a silicon semiconductor base having a conductor type of p-type including an acceptor impurity or an i-type (intrinsic type), is provided above a substrate 20 (serving as an example of a "substrate" according to the present invention) so as to be spaced apart from the substrate 20 and extend in a horizontal direction (this extending direction is an example of a "first direction" according to the present invention). A gate insulating layer 2 (serving as an example of a "first gate insulating layer" according to the present invention) is provided so as to be in contact with part of one of end surfaces of the p layer 1 in the extending direction of the p layer 1. A first gate conductor layer 3 (serving as an example of a "first gate conductor layer" according to the present invention) is provided so as to be in contact with the gate insulating layer 2 without contacting the p layer 1. A gate insulating layer 4 (serving as an example of a "second gate insulating layer" according to the present invention) is provided so as to be spaced apart from the gate insulating layer 2 in the extending direction of the p layer 1 and cover part of the surface of the p layer 1. A second gate conductor layer 5 (serving as an example of a "second gate conductor layer" according to the present invention) is provided so as to be in contact with the gate insulating layer 4 without contacting the p layer 1. An n+ layer 6 (serving as an example of a "first impurity layer" according to the present invention) is formed in part of the p layer 1 from part of the surface of the p layer 1 disposed between the gate conductor layer 3 and the gate conductor layer 5 so as to allow the p layer 1 to remain in the inside of the n+ layer 6. Likewise, an n+ layer 7 (serving as an example of a "second impurity layer" according to the present invention) not contacting the n+ layer 6 is formed in part of the p layer 1 from the surface of the p layer 1 disposed between the gate conductor layer 3 and the gate conductor layer 5 so as to allow the p layer 1 to remain in the inside of the n+ layer 7. According to the present embodiment, the n+ layer 6 and the n+ layer 7 face each other in a direction perpendicular to the extending direction of the p layer 1 (serving as an example of a "second direction" according to the present invention) with the p layer 1 interposed therebetween. Part of the n+ layer 6 and the part of the n+ layer 7 may face each other in a direction perpendicular to the extending direction of the p layer 1 with the p layer 1 interposed therebetween. The gate conductor layer 3 functions as a gate, one of the n+ layer 6 and the n+ layer 7 functions as a source, and the other of the n+ layer 6 and the n+ layer 7 functions as a drain to perform operation of a metal-oxide-semiconductor field-effect transistor (MOSFET). The n+ layer 6 and the n+ layer 7 may be formed in any parts of the p layer 1 as long as they are disposed so as to function as the drain and the source with respect to the gate conductor layer 3.

In this way, a single memory cell 10 is formed with the elements including the p layer 1, the gate insulating layer 2, the gate conductor layer 3, the gate insulating layer 4, the gate conductor layer 5, the n+ layer 6, and the n+ layer 7.

Furthermore, the n+ layer 7 is connected to a source line SL (serving as an example of a "source line" according to the present invention), and the gate conductor layer 5 is connected to a plate line PL (serving as an example of a "plate line" according to the present invention). The n+ layer 6 is connected to a bit line BL (serving as an example of a "bit line" according to the present invention). The gate conductor layer 3 is connected to a word line WL (serving as an example of a "word line" according to the present invention). The memory is operated by operating the potential of each of the source line SL, the bit line BL, the plate line PL, and the word line WL. Hereinafter, this memory device is referred to as a floating body extended random access memory (FX-RAM, see M. Kakumu et al., “Fully bulk CMOS compatible Key Shape Floating Body Memory (KFBM)”, Volume 4, July 2023 Memories-Materials, Devices, Circuits and Systems (2023)).

FIG. 1C illustrates a bird's-eye view of the structure of the memory cell according to the present embodiment.

Although the p layer 1 is a p-type semiconductor in FIGS. 1A to 1C, there may be a profile in the concentration of the impurity. Also, there may be a profile in the concentration of the impurity of the n+ layer 6 and n+ layer 7.

In a case where the n+ layer 6 and the n+ layer 7 are formed of a p+ layer in which positive holes are the majority carriers (hereinafter, a semiconductor region including an acceptor impurity at high concentration is referred to as a "p+ layer"), when the p layer 1 is an n-type semiconductor, the FX-RAM can be operated by using electrons as the writing carriers.

The substrate 20 illustrated in FIGS. 1A to 1C may be formed of any insulator, semiconductor material, or conductor material as long as an insulator can be formed on the substrate 20 and the substrate 20 can support the memory cell.

As long as the gate conductor layers 3 and 5 allow changes in potential of parts of the memory cell via the respective gate insulating layers 2 and 4, the gate conductor layers 3 and 5 may be formed of metal such as, for example, W, Pd, Ru, Al, TiN, TaN or WN, a metal nitride, or an alloy of metal or a metal nitride (including a silicide). The gate conductor layers 3 and 5 may have, for example, a laminated structure such as TiN/W/TaN or may be formed of a highly doped semiconductor.

The gate conductor layer 3 and the gate conductor layer 5 may be formed by a method in which the gate conductor layer 3 and the gate conductor layer 5 are simultaneously formed and then isolated from each other using a patterning technique.

For the gate insulating layer 2 and the gate insulating layer 4, any insulating layer used in a normal metal-oxide semiconductor (MOS) process such as, for example, an SiO₂ film, an SiON film, an HfSiON film, or an SiO₂/SiN laminated film can be used.

The gate insulating layer 2 and the gate insulating layer 4 may be formed by a method in which the gate insulating layer 2 and the gate insulating layer 4 are simultaneously formed and then isolated from each other.

Although, in the description of FIGS. 1A to 1C, the section of the p layer 1 perpendicular to line S-S' of the memory cell is described as having a rectangular shape, the vertical section may have any other shape such as a trapezoidal, polygonal, or circular shape.

Furthermore, even when the memory cell illustrated in FIGS. 1A to 1C is disposed in any direction with respect to the substrate, the memory operation as the FX-RAM is the same. As an example, the memory cell of FIGS. 1A to 1C rotated by 90 degrees about the axis of the semiconductor base 1 in a direction in which the semiconductor base 1 extends is illustrated in FIGS. 2A to 2C.

Although an example in which the n+ layer 6 and the n+ layer 7 are symmetrically arranged about the perpendicular direction of the gate conductor layer 3 is illustrated in FIGS. 1A to 2C, the length of the n+ layer 6 and the n+ layer 7 in a direction perpendicular to or parallel to the substrate 20 may be changed when an n+ layer 6P and the n+ layer 7 are formed in an isolated manner as illustrated in FIGS. 3A and 3B. A current flows between the n+ layer 6P and the n+ layer 7, and it is important that the direction of the flowing current intersects the perpendicular direction of the gate conductor layer 3 (the p layer 1 direction in FIGS. 3A and 3B).

Although an example in which the n+ layer 6P is in contact with the gate insulating layer 2 without contacting the insulating layer 4 is illustrated in FIG. 3A, when, similarly, the n+ layer 7 is in contact with the gate insulating layer 2, the FX-RAM operation can be performed even without contacting the gate insulating layer 4.

Although an example in which the gate insulating layer 4 and the gate conductor layer 5 cover the lower surface of the p layer is illustrated in FIG. 1B, the FX-RAM operation can be performed even in a case where the gate insulating layer 4 and the gate conductor layer 5 cover only the upper surface of the p layer 1 as illustrated in FIG. 3C. The FX-RAM operation can also be performed when the gate conductor layer 5 is separated and in contact with the gate insulating layer 4 at a plurality of positions.

FIG. 3D illustrates a case, as another modification, where the gate insulating layer 2 and the gate conductor layer 3 are formed on the surface of the p layer 1 including the corner, and, in plan view, in the direction in which the semiconductor base 1 extends, the position of an end portion of the impurity layer 7 on the gate conductor layer 3 side is coincident with the position of an end portion of the gate conductor layer 3 closest to the impurity layer 7. When a voltage is applied to the gate conductor layer 3, a known MOSFET operation that causes a current to flow between the impurity layer 6 and the impurity layer 7 along an interface between the gate insulating layer 2 and the p layer 1 can be performed. Accordingly, a memory operation similar to that performed with the structure illustrated in FIGS. 1A to 1C can be performed.

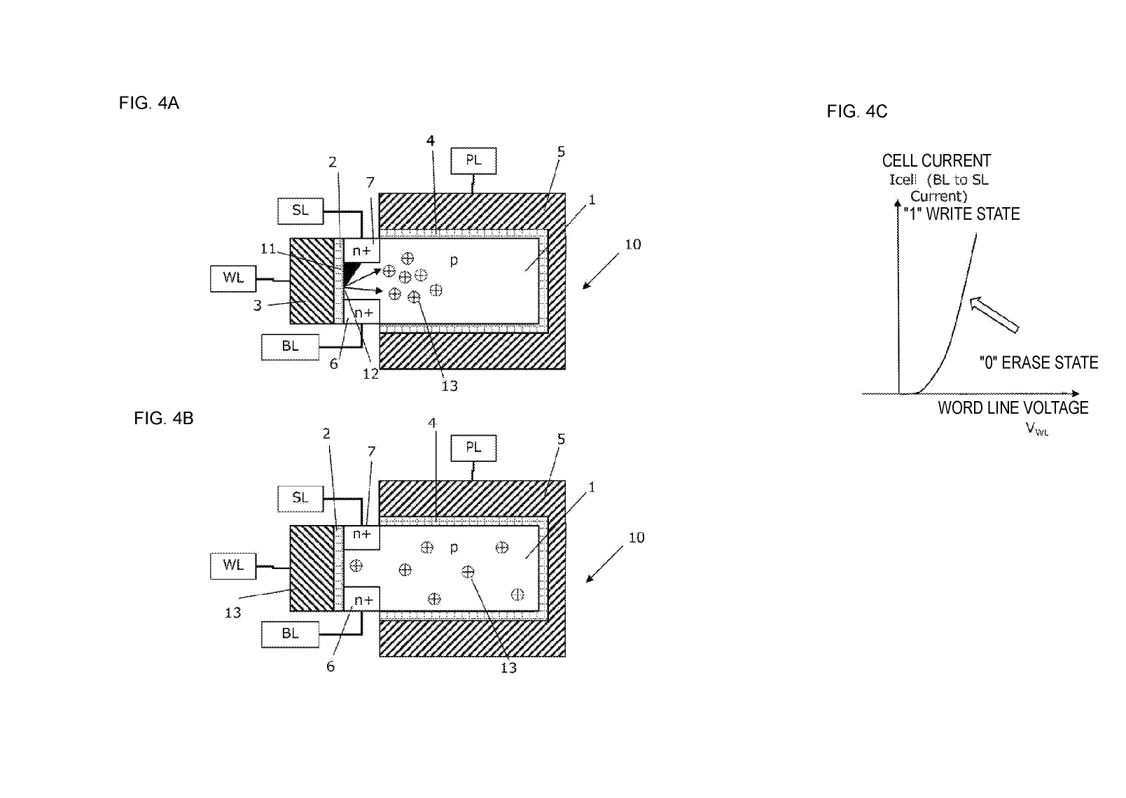

With reference to FIGS. 4A to 4C, a carrier behavior, storage, and a cell current during a write operation of the FX-RAM according to the one embodiment of the present invention are described. First, the following case is described: as illustrated FIG. 4A, the majority carriers of the n+ layer 6 and the n+ layer 7 are electrons; for example, n+ poly is used for the gate conductor layer 3 connected to the word line WL (hereinafter, poly-Si including donor impurities at high concentration is referred to as "n+ poly" ) and n+ poly is used for the gate conductor layer 5 connected to the plate line PL; and a p-type semiconductor is used as the p layer 1. For example, 1.2 V is input to the conductor layer n+ layer 6 to which the bit line BL is connected, for example, 0 V is input to the n+ layer 7 to which the source line SL is connected, for example, 1.5 V is input to the gate conductor layer 3 to which the word line WL is connected, and for example, -1 V is input to the gate conductor layer 5 to which the plate line PL is connected.

When these voltages are applied, the electrons flow from the n+ layer 7 toward the n+ layer 6. An inversion layer 11 is formed immediately below the gate insulating layer 2. Furthermore, an electric field is maximized at a pinch-off point 12, and an impact ionization is generated in this region. Due to this impact ionization, the electrons accelerated from the n+ layer 7 connected to the source line SL toward the n+ layer 6 connected to the bit line BL collide against an Si lattice, and kinetic energy at this time generates electron-positive hole pairs. Although a subset of the generated electrons flow toward the gate conductor layer 3, most of the generated electrons flow toward the n+ layer 6 connected to the bit line BL.

FIG. 4B illustrates a positive hole group 13 in the p layer 1 when the voltage of the plate line PL becomes -1 V, and bias of the word line WL and the bit line BL becomes 0 V immediately after writing. The generated positive hole group 13 is the majority carriers of the p layer 1, and the positive holes scatter at high speed from a high-concentration portion to a low-concentration portion within the level of a nano second due to a principle of dielectric relaxation time. The positive holes are stored in the p layer 1. The p layer 1 that is substantially a substrate of the MOSFET including the gate conductor layer 3 in a non-equilibrium state is charged to a positive bias. As a result, a threshold voltage of the MOSFET including the gate conductor layer 3 reduces due to a positive substrate bias effect by the positive holes temporarily stored in the p layer 1. In this way, as illustrated in FIG. 3C, the threshold voltage of the MOSFET including the gate conductor layer 3 connected to the word line WL becomes lower than that in a neutral state. This write state is assigned to logical storage data "1".

The above-described voltage conditions applied to the bit line BL, the source line SL, the word line WL, and the plate line PL are examples for performing the write operation. Other operating voltage conditions that enable the write operation may be used. For example, when the voltages applied to the bit line BL, the plate line PL, and the word line WL are respectively abbreviated to V-BL, V-PL, and V-WL, and it is assumed that 0 V is applied to the source line SL, combinations of the voltage application conditions such as the following combinations may be used: 1.0 V(V-BL)/-1 V(V-PL)/2.0 V(V-WL);1.0 V(V-BL)/-0.5 V(V-PL)/1.2 V(V-WL); and 1.5 V(V-BL)/-1 V(V-PL)/2.0 V(V-WL). The voltage relationship between the bit line BL and the source line SL may be interchanged.

The amount of the positive holes to be stored is determined by the volume of the p layer 1 surrounded by the gate conductor layer 5 illustrated in FIG. 1B. To increase the amount of the positive holes to be stored, it is sufficient that the sectional area of the p layer 1 be increased or the length of the p layer 1 in the horizontal direction be increased. In particular, when the dimension of the p layer 1 perpendicular to the substrate is increased, the amount of the positive holes to be stored can be increased without sacrificing the area of the memory cell in plan view.

Instead of generating the impact ionization, the gate induced drain leakage (GIDL) current may be flowed to generate the positive hole group (see, for example, E. Yoshida: “A Capacitorless 1T-DRAM Technology Using Gate-Induced Drain-Leakage (GIDL) Current for Low-Power and High-Speed Embedded Memory,” IEEE IEDM (2006)).

Next, with reference to FIGS. 5A to 5C, an erase operation mechanism of the FX-RAM according to the one embodiment illustrated in FIGS. 1A to 1C is described. From a state illustrated in FIG. 4B, the voltage of the bit line BL is set to 0 V, the voltage of 0 V is applied to the source line SL, the voltage of 1.5 V is applied to the plate line PL, and the voltage of 1.0 V is applied to the word line WL. As a result, as illustrated in FIG. 5A, an inversion layer 15 is formed at the interface of the p layer 1 by the voltage of 1.5 V applied to the plate line PL. The concentration of the positive holes of the p layer 1 in which "1" is written is sufficiently higher than those of the n+ layers 6 and 7 and the inversion layer 15. Thus, due to scattering caused by this concentration gradient, the positive holes flow into the n+ layers 6 and 7 and the inversion layer 15. In contrast, the concentration of the electrons in the n+ layers 6 and 7 and the inversion layer 15 is higher than that of the p layer 1. Thus, due to scattering caused by this concentration gradient, electrons 17 flow into the p layer 1. The electrons having flowed into the p layer 1 are recombined with the positive holes in the layer 1, and the electrons and the positive holes are annihilated. During erasing, the chances of the recombination of the positive holes and the electrons can be increased by forming the inversion layer 15. The electrons are continuously supplied from the source line SL and the bit line BL. Thus, excessive positive holes are recombined with the electrons in a very short time, and an initial state is returned. In this way, as illustrated in FIG. 5B, the MOSFET including the gate conductor layer 3 connected to the word line WL returns to the original threshold value. The erase state of this storage element becomes logical storage data "0".

As long as the positive voltage is applied through the plate line PL and the word line WL such that the inversion layer can be formed, the erase operation can be performed at any voltages the potentials of the bit line BL and the source line SL becomes. As another method of erasing data, the voltage conditions applied to the bit line BL, the source line SL, the word line WL, and the plate line PL may be combinations such as 0 V(V-BL)/2 V(W-PL)/0 V(V-WL), 0.4 V(V-BL)/2 V(V-PL)/0.5 V(V-WL),and 1 V(V-BL)/1.5 V(V-PL)/0 V(V-WL) while 0 V is applied to the source line SL. The above-described voltage conditions applied to the bit line BL, the source line SL, the word line WL, and the plate line PL are examples for performing the erase operation. Other operating conditions that enable the erase operation may be used.

As described in the memory operation, the cell current of the memory is controlled by the potential of the gate conductor layer 3, and the logical storage data is known. Accordingly, it is not desired that a current such as, for example, a punch through flow between the n+ layer 6 and the n+ layer 7 not controlled by the gate conductor layer 3. To suppress this, it is effective to control the current between the n+ layer 6 and the n+ layer 7 by the potential of the following gate conductor layer 3: in the section of the memory cell 10 including the n+ layer 6 and the n+ layer 7, for both the start point and the end point of a line segment connecting the n+ layer 6 and the n+ layer 7 closest to each other at the shortest distance, the gate conductor layer 3 is provided in a direction perpendicular to the line segment connecting at the shortest distance.

FIGS. 6A to 6D explain a cell arrangement of the memory device using a semiconductor element according to the one embodiment. FIG. 6A is a plan view, FIG. 6B is a vertical sectional view taken along line S-S' illustrated in FIG. 6A, FIG. 6C is a vertical sectional view taken along line S1-S1' illustrated in FIG. 6A, and FIG. 6D indicates the x direction (indicated by "row"), y direction (indicated by "column"), and the z direction (indicated by "stage") defined in FIGS. 6A to 6C. In an example illustrated in FIGS. 6A to 6C, the above-described FX-RAM cells are arranged on the substrate 20 and an insulating layer 21 (serving as an example of a "first insulating layer" according to the present invention) in a single row in the x direction (hereinafter, the x direction is indicated by a "row direction" or a "row number"), two columns in the y direction (hereinafter, the y direction is indicated by a "column direction" or a "column number") in the horizontal direction, and further, two stages in the vertical direction (z direction, hereinafter, the z direction is indicated by a "stage direction" or a "stage number" from the lowest stage) so as to be isolated from each other. That is, an example in which a plurality of the FX-RAM cells are provided such that a central axis of each memory cell extending in a direction in which the memory cell extends is parallel to a direction perpendicular to the substrate 20 is indicated.

Although an example of the arrangement of four memory cells is illustrated in FIGS. 6A to 6C, a larger number of the memory cells can be arranged in an actual memory device. Furthermore, the memory cells can be arranged in the x direction so as to make a three-dimensional arrangement of the memory cells.

Furthermore, as figure numbers in FIGS. 6A to 6C, forms such as a p layer 1yz and a gate insulating layer 2yz are indicated for corresponding cells. In these forms, after a numeric, "y" indicates a column and "z" indicates a stage. When the character is "a", this means a first column or a first stage, and when the character is "b", this means a second column or a second stage (hereinafter, the columns and the stages may be collectively represented only by a numeric. For example, the p layer 1aa to p layer 1bb are collectively represented as p layers 1).

FIG. 6A illustrates a plan view of the second stage in which two cells are disposed in the x-y plane. For example, the memory cell 10ab at the first row and first column on the second stage includes the p layer 1ab, the gate insulating layer 2ab, the gate conductor layer 3b, the gate insulating layer 4ab (illustrated in FIG. 6B), the gate conductor layer 5b, n+ layer 6ab, and the n+ layer 7ab. Furthermore, the n+ layer 6ab is connected to a conductor layer 8a (serving as an example of a "first conductor layer" according to the present invention). The n+ layer 7ab is connected to a conductor layer 9a (serving as an example of a "second conductor layer" according to the present invention). Thus, a single memory cell is formed. The first gate conductor layer 3b is connected to the word line, the second gate conductor layer 5b is connected to the plate line, the first conductor layer 8a is connected to the bit line, and the second conductor layer 9a is connected to the source line.

The gate conductor layer 3b is shared between the cells in the column direction. For example, the gate conductor layer 3b is shared between the memory cells 10ab and 10bb including the p layers 1ab and 1bb. Likewise, the gate conductor layer 3a is shared between the memory cells including the p layers 1aa and 1ba. Likewise, the gate conductor layer 5b is shared between the cells in the column direction. The conductor layer 9a is shared between two adjacent cells and all the cells adjacent to each other in the vertical direction.

FIG. 6B illustrates a sectional view of two cells on the two stage at the first row disposed in the x-z plane taken along the line S-S' illustrated in FIG. 6A. The memory cell at the first row and first column on the second stage includes the elements described above. The memory cell 10aa at the first row and first column on the first stage includes the p layer 1aa, the gate insulating layer 2aa, the gate conductor layer 3a, the gate insulating layer 4aa, the gate conductor layer 5a, n+ layer 6aa (illustrated in FIG. 6C), and the n+ layer 7aa (illustrated in FIG. 6C).

FIG. 6C illustrates a sectional structure of four cell arrays taken along line S1-S1' illustrated in FIG. 6A. The conductor layer 9a is shared between two adjacent cells in the x-y plane and the cells in the stage direction. For example, the conductor layer 9a is shared between the cells including the p layers 1aa, 1ab, 1ba, and 1bb. The conductor layer 9a is connected to the source line.

FIGS. 7A and 7B illustrate an example of disposition of the memory cells that realizes a higher-density memory device according to the one embodiment of the present invention. FIG. 7A is a plan view. FIG. 7B is a vertical sectional view taken along line S-S' illustrated in FIG. 7A. In FIGS. 7A and 7B, the elements that are the same as or similar to those illustrated in FIGS. 1A to 1C are denoted by reference numerals the numeric parts of which are the same as those of FIGS. 1A to 1C.

In FIG. 7A, the components illustrated in FIGS. 6A to 6C are represented as follows: the p layers 1aa to 1bb are collectively represented as the p layers 1;the gate insulating layers 2aa to 2bb are collectively represented as gate insulating layers 2; the gate conductor layers 3a to 3b are collectively represented as gate conductor layers 3; the gate insulating layers 4aa to 4bb are collectively represented as gate insulating layers 4; the gate conductor layers 5a to 5b are collectively represented as gate conductor layers 5; the n+ layers 6aa to 6bb are collectively represented as n+ layers 6; the n+ layers 7aa to 7bb are collectively represented as n+ layers 7; the wiring conductor layers 8a and 8b are represented as wiring conductor layers 8; the wiring conductor layer 9a is represented as a wiring conductor layer 9; and the memory cells 10aa to 10bb are collectively represented as memory cells 10. FIG. 7B is a sectional view taken along line S-S' illustrated in FIG. 7A.

In FIG. 7A, the elements of the cell arrays illustrated in FIG. 6C are each represented as "Array". FIG. 7A illustrates an example in which a total of twelve cells are disposed on the insulating layer 21 in contact with the substrate 20 such that unit Arrays are arranged while being placed in a normal direction, a left-right inverted direction, and a normal direction, and the gate conductor layers 3 are shared between the adjacent cells. Each of the unit Arrays is a unit array illustrated in FIG. 5A. FIG. 7B illustrates a sectional view in which the unit Arrays illustrated in FIG. 7A are similarly arranged while being placed in the normal direction, the left-right inverted direction, and the normal direction.

In the example illustrated in FIGS. 7A and 7B, the memory cells are developed rightward. However, the memory cells may be developed upward in FIG. 7A or in the vertical direction from the substrate 20 in FIG. 7B.

The length of the Arrays illustrated in FIGS. 7A and 7B is one of the significant elements to determine a memory cell density. This structure is highly similar to a dynamic random access memory (DRAM) of a three-dimensional structure. For the DRAM, the capacitor portion, that is, in FIGS. 7A and 7B, the contact area between the p layers 1 and the gate insulating layers 4 is a significant element. When it is not the case that this capacitance is greater than or equal to ten times the capacitance of the bit line in the DRAM, signals cannot be read. That is, the length in the Array direction in plan view of FIG. 7A is to be a greater than or equal to a certain value so that the capacitance of the cells satisfies the above-described interface conditions. In contrast, in the case of the FX-RAM, the above-described length is determined by a data retention time. Thus, the length of the Arrays can be reduced compared to the DRAM. That is, there is an advantage in that the cell size can be reduced compared to the DRAM.

Furthermore, when the memory cells illustrated in FIGS. 2A to 2C are used, the cells may be arranged as illustrated in FIGS. 8A and 8B. In this arrangement, the memory cell arrays illustrated in FIGS. 7A and 7B are rotated by 90 degrees about a central axis of the memory cell arrays in a direction in which the memory cell arrays extend. In this case, the gate conductor layers 3 and 5 are disposed so as to be perpendicular to the substrate 20, and the wiring conductor layers 8 and 9 are disposed in the horizontal direction.

The present embodiment has the following features.

### Feature 1

The FX-RAM according to the one embodiment of the present invention includes the semiconductor base p layer 1, the first gate insulating layer 2, the first gate conductor layer 3, the gate insulating layer 4, the second gate conductor layer 5, the first impurity layer 6, and the second impurity layer 7. Accordingly, compared to the related-art example (see, for example, U.S. Patent Application Publication No. 2023/11798616 B2 and M. Kakumu et al., “Fully bulk CMOS compatible Key Shape Floating Body Memory (KFBM)”, Volume 4, July 2023 Memories-Materials, Devices, Circuits and Systems (2023)), the number of operation terminals can be reduced, the operation can be simplified, and the density of the memory can be increased.

### Feature 2

Compared to the related-art example (see, for example, U.S. Patent Application Publication No. 2023/0298659 A1), in the FX-RAM according to the one embodiment of the present invention, the wiring conductor layer connecting the memory cells can be disposed between the memory cells. Accordingly, high-density cell arrangement can be realized. Furthermore, unlike the DRAM, the size of the memory cells of the FX-RAM are determined not by the capacitor ratio of the bit line and the capacitor but by the data retention state. Accordingly, particularly in the three-dimensional structure, the cell size of the FX-RAM can be smaller than that of the DRAM.

### Feature 3

In the FX-RAM according to the one embodiment of the present invention, the majority carriers generated in the write of the logical data "1" can be stored in the first semiconductor base p layer 1, and the number of the majority carriers can be increased. Accordingly, information retention time can be increased. Furthermore, in the data erase, the positive voltage is applied to the second gate conductor layer 5 connected to the plate line PL. Thus, the inversion layer is formed at the interface between the second gate insulating layer and the p layer 1, and the recombination area between the excess positive holes and the electrons can be increased. This facilitates the erase. Accordingly, the operation margin of the memory can be increased and the power consumption can be reduced. This leads to high-speed operation of the memory.

### Feature 4

In the FX-RAM according to the one embodiment of the present invention, a plurality of memory cells can be laminated with respect to the vertical direction of the substrate, and the plurality of memory cells can be connected to the conductor layer 8 connected to the source line SL and the conductor layer 7 connected to the bit line BL in the vertical direction. Accordingly, compared to the related art in which the memory cells are arranged two-dimensionally, the length of wiring can be reduced, parasitic resistance and the parasitic capacitance can be reduced compared to the related-art example, the memory can be operated at high-speed, and the operation margin of the memory can be increased. In the related-art arrangement of the memory cell, how to connect as many memory cells as possible to the same bit line is important for reducing the area in plan view. However, connecting many cells to the same bit line increases two-dimensional layout dependency of the parasitic resistance and the parasitic capacitance. This arises a problem in that the memory operation margin is reduced.

### Feature 5

In the FX-RAM according to the one embodiment of the present invention, the vertical thickness and the horizontal length of the p layer 1 of the memory cell can be freely adjusted without sacrificing the memory density in plan view. Accordingly, the number of carriers in the write can be increased, and the margin of the memory operation can be increased.

### Feature 6

In the FX-RAM according to the one embodiment of the present invention, spacing between the memory cells in the vertical direction with respect to the substrate can be increased without sacrificing the memory density. Accordingly, the spacing between the gate conductor layers 3 of each memory in the vertical direction can be increased, and the parasitic capacitance can be reduced compared to the related-art example. Furthermore, the thickness of the gate conductor layer 3 in the vertical direction can be substantially increased, and accordingly, the parasitic resistance can be reduced, and high-speed operation of the memory can be facilitated.

In addition, various embodiments and modifications of the present invention can be made without departing from the broad spirit and scope of the present invention. Each of the embodiments described above is provided for describing an example of the present invention and does not limit the scope of the present invention. The above-described examples and modifications may be combined with each other in any combination. Furthermore, embodiments in which a subset of constituent elements of the above-described embodiment are omitted as necessary also fall within the scope of the technical thought of the present invention.

When the semiconductor element according to the present invention is used, a semiconductor memory device having a higher density, higher speed, and higher operation margin than the related-art semiconductor memory device can be provided.

What is claimed is:

1. A memory device using a semiconductor element, the memory device comprising:
a memory cell including
a semiconductor base extending in a first direction parallel to a substrate,
a first gate insulating layer in contact with one end surface of the semiconductor base in the first direction,
a first gate conductor layer in contact with the first gate insulating layer without contacting the semiconductor base,
a second gate insulating layer spaced apart from the first gate insulating layer in the first direction and covers part of the semiconductor base,
a second gate conductor layer in contact with the second gate insulating layer, and
a first impurity layer and a second impurity layer provided between the first gate conductor layer and the second gate conductor layer and formed in part of the semiconductor base, and
wherein the first impurity layer and the second impurity layer are disposed so as to function as a drain or a source for the first gate conductor layer.

2. The memory device according to claim 1,
wherein the first impurity layer is connected to a bit line, the second impurity layer is connected to a source line, the first gate conductor layer is connected to a word line, and the second gate conductor layer is connected to a plate line, and
wherein memory write and/or memory erase is performed by applying voltages respectively to the source line, the bit line, the plate line, and the word line.

3. The memory device according to claim 1,
wherein a memory write operation is performed by performing an operation in which voltages to be applied to a bit line, a source line, a word line, and a plate line are controlled so as to generate an electron group and a positive hole group in the semiconductor base and the second impurity layer using impact ionization due to a current flowed between the first impurity layer and the second impurity layer or using a gate induced drain leakage current, and an operation which causes part or an entirety of the electron group or the positive hole group, out of the generated electron group and the generated positive hole group, as majority carriers in the semiconductor base to remain in the semiconductor base, and
wherein a memory erase operation is performed by controlling the voltages to be applied to the bit line, the source line, the word line, and the plate line to extract the remaining electron group or the remaining positive hole group as the majority carriers in the semiconductor base from at least one of the first impurity layer and the second impurity layer.

4. The memory device according to claim 1,
wherein part of the first impurity layer and part of the second impurity layer face each other in a second direction perpendicular to the first direction with the semiconductor base interposed therebetween.

5. The memory device according to claim 1,
wherein the first impurity layer or the second impurity layer is in contact with the first gate insulating layer or the second gate insulating layer.

6. The memory device according to claim 1,
wherein, in a section of the memory cell including the first impurity layer and the second impurity layer, for both a start point and an end point of a line segment connecting the first impurity layer and the second impurity layer at a shortest distance, the first gate conductor layer is disposed in a direction perpendicular to the line segment.

7. The memory device according to claim 1,
wherein a plurality of the memory cells, a plurality of the first impurity layers, and a plurality of the second impurity layers are provided,
wherein the plurality of memory cells having a shape identical to a shape of the memory cell formed in the semiconductor base are provided on a first insulating layer disposed on the substrate in a direction perpendicular to the substrate such that central axes of the plurality of memory cells in directions in which the respective memory cells extend are parallel to each other, and
wherein a first conductor layer connected to the plurality of first impurity layers of the plurality of memory cells, and
a second conductor layer connected to the plurality of second impurity layers of the plurality of memory cells are provided.

8. The memory device according to claim 7,
wherein, among the plurality of memory cells adjacent to each other in a parallel direction or a perpendicular direction relative to the substrate, the first gate conductor layer connected to each memory cell is shared.

9. The memory device according to claim 7,
wherein, among the plurality of memory cells adjacent to each other in a parallel direction or a perpendicular direction relative to the substrate, the second gate conductor layer connected to each memory cell is shared.

10. The memory device according to claim 7,
wherein, among the plurality of memory cells adjacent to each other in a parallel direction or a perpendicular direction relative to the substrate, the first conductor layer connected to each memory cell is shared.

11. The memory device according to claim 7,
wherein, among the plurality of memory cells adjacent to each other in a parallel direction or a perpendicular direction relative to the substrate, the second conductor layer connected to each memory cell is shared.
